(19) United States
(12) Patent Application Publication
(10) Pub. No.: US 2009/0174422 A1
(43) Pub. Date: Jul. 9, 2009

(54) Probe Card and Manufacturing Method Thereof

(75) Inventor: Kazumichi Machida, Hyogo (JP)

Correspondence Address: RADER FISHMAN & GRAUER PLLC, LION BUILDING, 1233 20TH STREET N.W., SUITE 501, WASHINGTON, DC, 20036, US

(73) Assignee: JAPAN ELECTRONIC MATERIALS CORPORATION, Hyogo (JP)

(21) Appl. No.: 11/992,485

(22) PCT Filed: Sep. 8, 2006
(86) PCT No.: PCT/JP2006/317891

§ 371 Date: Mar. 24, 2008

(30) Foreign Application Priority Data
Sep. 26, 2005 (JP) 2005-278087

(51) Int. Cl. G01R 31/02; H05K 13/00

(52) U.S. Cl. 324/754; 29/854

(57) ABSTRACT

A probe card usable at a higher temperature and a manufacturing method thereof are provided. Each of the junction interfaces of the contact probes and the electrode pads is made from the same metal material, wherein each of the junction interfaces is irradiated with ions in vacuum to remove impurities, followed by positioning so as to associate each of the junction interfaces while maintaining a vacuum state. Therefore, mutual bonding of the bonds in the respective junction interfaces is achieved to associate the junction interfaces with one another at normal temperature, where it is not necessary to form a melting layer having a low melting point between the contact probes and the electrode pads in such a case as using the melting layer to join them. Accordingly, if a metal material having a high melting point is used for the contact probes and the electrode pads, the contact probes and the electrode pads do not melt until high temperature is reached, which makes it possible to provide a probe card usable at a higher temperature.

### TECHNICAL FIELD

The present invention relates to a probe card and a manufacturing method thereof, and more specifically to improvement of a method for joining contact probes and a substrate.

### BACKGROUND ART

Probe cards have been known as being used to electrically connect a test subject such as a semiconductor integrated circuit and a tester device by bringing contact probes into contact with the test object (e.g., Patent Documents 1 and 2). A tester device is provided to examine electrical characteristics of a test subject which is connected thereto via a probe card. A probe card is formed by, for example, aligning and arranging resilient metal contact probes on a substrate on which a wiring pattern is formed.

One end of each of the contact probes is connected to the substrate through a melting layer while the other end thereof forms a contact portion which is brought into contact with a test subject. A metallic electrode pad is attached to the wiring pattern on the substrate, and a metal material having a low melting point is formed as a melting layer between the electrode pad and one end of the contact probe. When the contact probes are joined to the substrate, the meld layer is melted by heating and solidified by cooling, which causes the contact probes and the electrode pad to be attached to one another, thereby fixing the contact proves on the substrate.

[Patent Document 1] Japanese Unexamined Patent Application Publication No. 2005-140677

[Patent Document 2] Japanese Unexamined Patent Application Publication No. 2005-140678

### DISCLOSURE OF THE INVENTION

### Problems to be Solved by the Invention

However, when a probe card containing contact probes which are joined on a substrate through a melting layer is used at a high temperature, a problem that the melting layer which has a low melting point melts to be heated over its melting point is caused.

Moreover, if the contact probes are joined on the substrate through the melting layer, electric resistance is increased in the junction portions, and there are cases of generating distortion and deformation in the contact probes caused by heating and generating mounting errors in each of the junction portions. If distortion and deformation are generated in the contact probes, or if mounting errors are present in each of the junction portions, contact positions between the contact probes and a test subject are displaced. Such an increase in electric resistance and displacement of contact positions between the contact probes and a test subject may cause a possibility of adverse effects in testing electric characteristics of a test subject.

The present invention was achieved in view of the aforementioned problems, and an object thereof is to provide a probe card usable at a higher temperature and a manufacturing method thereof. Another object of the present invention is to provide a probe card capable of suppressing electric resistance between contact probes and a substrate and a manufacturing method thereof. Yet another object of the present invention is to provide a probe card capable of preventing displacement of contact positions between contact probes and a test subject and a manufacturing method thereof.

### Means for Solving the Problem

A probe card according to a first aspect of the present invention is provided with: contact probes for use in contact with a test object; and a substrate having electrode pads formed on its surface to be connected to the contact probes, where respective junction interfaces of the contact probes and the electrode pads are made from the same metal material, and where the contact probes and the electrode pads are joined to one another by mutually associating the junction interfaces thereof in vacuum.

With such a construction, the contact probes and the electrode pads can be joined at normal temperature. That is, respective junction interfaces of the contact probes and the electrode pads are associated with one another in vacuum to allow for mutual bonding of the bonds of metal atoms which constitute each of the junction interfaces, so that the contact probes and the electrode pads can be firmly joined without heating.

Particularly since the same metal material is used for each of the junction interfaces of the contact probes and the electrode pads, the distances between the metal atoms at the junction interfaces are equivalent, which makes equivalent the distances between the bonds of the metal atoms. Accordingly, the density of the bonds is substantially equivalent in each of the junction interfaces of the contact probes and the electrode pads, which allows for highly-dense bonding of the bonds, so that the contact probes and the electrode pads can be joined more firmly.

As the contact probes and the electrode pads are bonded to one another by mutual bonding of the bonds, it is not necessary to form a melting layer having a low melting point between the contact probes and the electrode pads in such a case as using the melting layer to join them. Accordingly, if the contact probes and the electrode pads are made from a metal material having a high melting point, the contact probes and the electrode pads do not melt until high temperature is reached, which makes it possible to provide a probe card usable at a higher temperature.

Moreover, electric resistance can be made smaller in the junction portions in comparison with a construction where the contact probes are joined onto the substrate through a melting layer, so that electric resistance between the contact probes and the substrate can be decreased.

Furthermore, in comparison with a construction where the contact probes are joined onto the substrate through a melting layer, joining the contact probes and the electrode pads at normal temperature makes it possible to prevent distortion and deformation of the contact probes caused by heating, and mounting errors in each of the junction portions. Therefore, displacement of contact positions between the contact probes and a test subject can be prevented.

In a method for manufacturing a probe card according to a second aspect of the present invention, the probe card is manufactured by joining contact probes for use in contact with a test object and metal pads formed on the surface of a substrate, and the method includes: an interface forming step to form each of junction interfaces of the contact probes and the electrode pads with the same metal material; an interface activating step to remove impurities attached to each of the junction interfaces of the contact probes and the electrode pads in vacuum so as to activate each of the junction interfaces; and an interface joining step to associate and join the junction interfaces of the contact probes and the metal pads with one another while keeping a vacuum state after implementing the interface activating step.

With such a configuration, it is made possible to manufacture a probe card which exhibits effects similar to those of the probe card according to the first aspect of the present invention. In particular, since impurities attached to each of the junction interfaces are removed in vacuum, impurities in the atmosphere and impurities removed from each of the junction interfaces are hard to adhere to each of the activated junction interfaces, and the junction interfaces are associated with one another in this state, so that the junction interfaces can be joined from one another in a satisfactory manner.

In a method for manufacturing a probe card according to a third aspect of the present invention, the interface activating step includes irradiating each of the junction interfaces of the contact probes and the metal pads with ions in order to remove impurities attached to each of the junction interfaces in vacuum, thereby activating each of the junction interfaces. Such a configuration makes it possible to remove impurities attached to each of the junction interfaces by only the simple operation of irradiating each of the junction interfaces of the contact probes and the electrode pads with ions in vacuum, thereby to activate each of the junction interfaces.

A method for manufacturing a probe card according to a fourth aspect of the present invention includes an interface smoothing step to smooth each of the junction interfaces of the contact probes and the electrode pads, wherein the interface activating step is carried out after the interface smoothing step. With such a configuration, each of the junction interfaces of the contact probes and the electrode pads is smoothed to secure a large junction area thereof.

### EFFECTS OF THE INVENTION

According to the present invention, a probe card usable at a higher temperature can be provided by the contact probes and the electrode pads which are made from by a metal material having a high melting point. Moreover, in comparison with a construction where the contact probes are joined onto a substrate through a melting layer, electric resistance can be made smaller in junction portions, allowing reduction of electric resistance between the contact probes and the substrate. Furthermore, in comparison with a construction where the contact probes are joined onto the substrate through a melting layer, joining the contact probes and the electrode pads at normal temperature makes it possible to prevent displacement of contact positions between the contact probes and a test subject.

### BEST MODE FOR CARRYING OUT THE INVENTION

FIG. 1 is a perspective view showing an outline of a method for manufacturing a probe card 1 according to an embodiment of the present invention, where FIG. 1(a) shows a state before contact probes 10 are joined to a contact substrate 20, and FIG. 1(b) shows a state after the contact probes 10 are joined to the contact substrate 20. The probe card 1 is provided with a plurality of the contact probes 10 to be brought into contact with a test subject such as a semiconductor integrated circuit, and the contact substrate 20 for holding the contact probes 10.

The contact substrate 20 is made of a silicone plate and has a wiring pattern 21 on its surface. Two columns of plate-like electrode pads 22 are aligned and arranged on a surface of the contact substrate 20 so as to be joined to the contact probes 10, where the electrode pads 22 are connected to the wiring pattern 21. The surface of each of the electrode pads 22 is provided as a junction interface 23 to be joined to the contact probes, and formed into a flattened face.

The electrode pads 22 are made of metal materials such as nickel-cobalt (Ni—Co), palladium-nickel (Pd—Ni), palladium-cobalt (Pd—Co), tungsten (W), and nickel-tungsten (Ni—W). The wiring pattern 21 extends to circumferential portions of the contact substrate 20 and is connected to a tester device by a wiring member mounted onto the circumferential portions of the contact substrate 20.

For example, the contact substrate 20 is suspended from a main substrate made of a glass-epoxy multilayer wiring board by a flexible substrate. The main substrate is mounted onto a probe device and thereby connected to the tester device for testing electric characteristics of a test subject. The flexible substrate is connected to the circumferential portions of the contact substrate 20, and the contact probes 10 are electrically connected to the tester device via the electrode pads 22, wiring pattern 21, a flexible substrate and a main substrate.

The contact probes 10 are made from the same metal materials as that of the electrode pads 22, i.e. resilient conductive metal materials such as nickel-cobalt (Ni—Co), palladium-nickel (Pd—Ni), palladium-cobalt (Pd—Co), tungsten (W), and nickel-tungsten (Ni—W). Each of the contact probes 10 is formed in an arch shape, providing a contact portion 11 to be brought into contact with a test subject in one end, and a junction portion 12 which is joined to the contact substrate 12 in the other end.

The junction portion 12 of each of the contact probes 10 provides a junction interface 13 which is joined to the electrode pad 22 of the contact substrate 20. The junction interface 13 is formed into a flattened face whose area is smaller than that of the junction interface 23 of the electrode pad 22. Each of the contact probes 10 is supported in the junction portion 12 on the contact substrate 20 in a cantilevered state, being curbed into an arch shape from the junction portion 12 on its top end side so as to be away from the contact substrate 20. More specifically, each of the contact probes 10 is formed into a two-stage arch shape having a bent portion in the center thereof. The contact portion 11 protrudes toward an opposite side of the contact substrate 20 in a top end portion of the contact probe 10.

In the present embodiment, as shown in FIG. 1(a), circumferences of the plurality of the contact probes 10 are solidified by materials such as copper (Cu) so as to prevent changes in relative positions thereof and integrally treated as a block body 30. Each of the junction interfaces 13 of the plurality of the contact probes 10 is exposed from one face of the block body 30 (referred to as an “opposing face 31” hereinafter) to the outside, and the opposing face 31 is made to face the contact substrate 20 and positioned to connect the respective junction interfaces 13 of the contact probes 10 to the junction interfaces 23 of the corresponding electrode pads 22, so that the plurality of the contact probes 10 can be positioned at once.

The block body 30 as stated above can be formed by a known method such as laminating thin copper films and selectively forming grooves by etching or the like in each layer while filling a metal material in the grooves in order to form the contact proves 10. Therefore, the contact probes 10 can be formed by the metal material which is continuously filled in the groove of each layer of the block body 30.

The block body 30 is positioned with respect to the contact substrate 20 and each of the contact probes 10 is joined to the corresponding electrode pad 22, followed by melting the copper of the block body 30 by using chemicals or the like, so that the contact substrate 20 on which the plurality of the contact probes 10 is supported in a cantilevered state can be created as shown in FIG. 1(b).

However, instead of mounting the contact probes 10 onto the contact substrate 20 by using the block body 30 as shown in the present embodiment, the plurality of the contact probes 10 may be integrally treated by, for example, connecting the plurality of the contact probes 10 by a support layer at the time of forming the contact probes 10, or appropriately cutting out a base board which supports the plurality of the contact probes 10 at the time of forming the contact probes 10. Alternatively, instead of mounting the plurality of the contact probes 10 onto the contact substrate 20 at once, the contact probes 10 may be mounted onto the contact substrate 20 one by one or in a unit of several numbers.

FIG. 2 is provided to explain a method for manufacturing the probe card 1 of FIG. 1, showing a schematic cross-sectional diagram of a probe card manufacturing device 40. FIG. 3 is a flowchart showing an example of a joining process at normal temperature as the method for manufacturing the probe card 1 of FIG. 1. FIG. 4 is a model diagram to explain the principle of the joining process at normal temperature.

The probe card manufacturing device 40 has a vacuum chamber 41, manipulator 42, and ion irradiation apparatus 43. The junction interface 13 of each of the contact probes 10 in the opposing face 31 of the block body 30 and the junction interface 23 of each of the electrode pads 22 on the contact substrate 20 are made from with the same metal material and formed into a smooth face in which a height difference of the surface unevenness is from several tens to several hundreds of Å, using a known polishing method such as a so-called float polishing method (i.e. smoothing process: step S101 of FIG. 3). Each of the junction interfaces 13 and 23 of the contact probes 10 and the electrode pads 22 is smoothed, so that expansion of a junction area thereof can be ensured.

Thereafter, air inside the vacuum chamber 41 is sucked out from an exhaust port 44 installed to the vacuum chamber 41, as shown in FIG. 2(a), so that atmospheric pressure inside the vacuum chamber 41 is brought into a high vacuum atmosphere of about 10-7 to 10-9 Pa (i.e. step S102 of FIG. 3). The contact substrate 20 is then fixed to a predetermined position inside the vacuum chamber 41, and ions are irradiated toward the opposing face 31 of the block body 30 and the surface of the contact substrate 20 by the ion irradiation apparatus 43 in a state that the block body 30 is held by the manipulator 42 (i.e. cleaning process: step S103 of FIG. 3).

Ions irradiated by the ion irradiation apparatus 43 are preferably inert ions which are hard to bond with metal atoms, and argon ions are irradiated in the present embodiment. In the cleaning process, argon ions collide with the junction interface 13 of each of the contact probes 10 in the opposing face 31 of the block body 30 and the junction interface 23 of each of the electrode pads 22 on the contact substrate 20, where energy of the collision cuts off bonds of metal atoms which constitute each of the junction interfaces 13 and 23, so that impurities attached to each of the junction interfaces 13 and 23 are removed.

When bonds 51 of metal atoms 50 which constitute each of the junction interfaces 13 and 23 are cut off by the cleaning process as shown in FIG. 4(a), the bonds 51 are activated and brought into a state that the bonds easily bond with bonds of other atoms. In this state, the block body 30 is positioned to be connected to the junction interfaces 23 of the electrode pads 22 corresponding to the respective junction interfaces 13 of the contact probes 10, as shown in FIG. 2(b) (i.e. step S104 of FIG. 3). Therefore, the junction interfaces 13 and 23 of each of the contact probes 10 and the electrode pads 22 are associated with one another in vacuum, where mutual bonding of the bonds 51 of each of the junction interfaces 13 and 23 causes the junction interfaces 13 and 23 to be joined from one another at normal temperature as shown in FIG. 4(b). Thereafter, a process to remove copper of the block body 30 shall be performed by melting or the like, as stated above.

A phenomenon observed through the activated bonds 51 which are thus associated to bond with one another is assumed to be based on spontaneous mutual bonding (or self alignment) of the bonds 51 according to the principle that bonds are stabilized when a free energy level owned by each of the bonds 51 exhibits a lowest state. Since impurities attached to each of the junction interfaces 13 and 23 are removed in a high vacuum atmosphere, impurities in the atmosphere and impurities removed from each of the junction interfaces 13 and 23 by the cleaning process are hard to adhere to each of the activated junction interfaces 13 and 23, and each of the junction interfaces 13 and 23 are associated with one another in this state, so that the junction interfaces 13 and 23 can be joined from one another in a satisfactory manner.

The present embodiment makes it possible to join the contact probes 10 and the electrode pads 22 at normal temperature. That is, since each of the junction interfaces 13 and 23 of each of the contact probes 10 and the electrode pads 22 are associated with one another in vacuum to allow mutual bonding of the bonds 51 of the metal atoms 50 which constitute each of the junction interfaces 13 and 23, the contact probes 10 and the electrode pads 22 can be firmly joined without heating.

Particularly because the same metal material is used for each of the junction interfaces 13 and 23 of the contact probes 10 and the electrode pads 22, an equivalent distance among atoms of the metal atoms 50 and an equivalent distance among the bonds 51 of the metal atoms 50 are obtained in each of the junction interfaces 13 and 23. Accordingly, the density of the bonds 51 is substantially equivalent in each of the junction interfaces 13 and 23 of the contact probes 10 and the electrode pads 22, which allows the bonds 51 to bond from one another with high density, where the contact probes 10 and the electrode pads 22 can be joined more firmly.

As the contact probes 10 and the electrode pads 22 are thus constructed to bond from one another by mutual bonding of the bonds 51, it is not necessary to form a melting layer having a low melting point between the contact probes 10 and the electrode pads 22 in such a case as using the melting layer to join them. Accordingly, if the contact probes 10 and the electrode pads 22 are formed by a metal material having a high melting point, the contact probes 10 and the electrode pads 22 do not melt until high temperature is reached, which makes it possible to provide the probe card 1 usable at a higher temperature.

Moreover, electric resistance can be made smaller in junction portions in comparison with a construction where the contact probes 10 are joined on the contact substrate 20 through a melting layer, so that electric resistance can be decreased between the contact probes 10 and the contact substrate 20.

Furthermore, in comparison with a construction where the contact probes 10 are joined on the substrate 20 through a melting layer, joining the contact probes 10 and the electrode pads 22 at normal temperature makes it possible to prevent distortion and deformation caused in the contact probes by heating and mounting errors in each of the junction portions. Therefore, displacement of contact positions between the contact probes 10 and a test subject can be prevented.

Explanation was made for, but not limited to, the construction of forming the electrode pads 22 on the contact substrate 20 and connecting the wiring pattern 21 on the contact substrate 20 to the electrode pads 22 in the above embodiment, where the electrode pads may be constructed so as to be attached onto the wiring pattern of the contact substrate. The electrode pads may be made from a metal material which differs from that of the wiring pattern, or may be integrally formed with the same metal material as that of the wiring pattern.

Each of the junction interfaces 13 and 23 of the contact probes 10 and the electrode pads 22 is not limited to be formed into a flattened face, where a curved shape and an uneven shape may be employed. For example, either the contact probes or the electrode pads may have the junction interfaces formed into a protruded shape while the remaining one has the junction interfaces formed into a corresponding recessed shape in order to associate the junction interfaces by engaging with one another.

Also, a construction of using the same metal material to entirely form the contact probes 10 and the electrode pads 22 is not limiting, where any configurations may be applied as long as the same metal is used to form at least each of the junction interfaces 13 and 23. Accordingly, the construction of forming the contact probes 10 entirely with the same metal material as that of the electrode pads 22 is not limiting, so that the contact probes made of, for example, various kinds of parts where a plunger is arranged to be expansible and contractible within a barrel may be constructed to have portions including the junction interfaces which are exclusively made from the same metal material as that of the electrode pads.

The contract substrate 20 is not limited to a silicone substrate, where a substrate made of other materials such as a glass-epoxy substrate may be employed.

### BRIEF DESCRIPTION OF THE DRAWINGS

FIG. 1 is a perspective view showing an outline of a method for manufacturing a probe card according to an embodiment of the present invention; FIG. 1(a) shows a state before contact probes are joined to a contact substrate; and FIG. 1(b) shows a state after the contact probes are joined to the contact substrate.

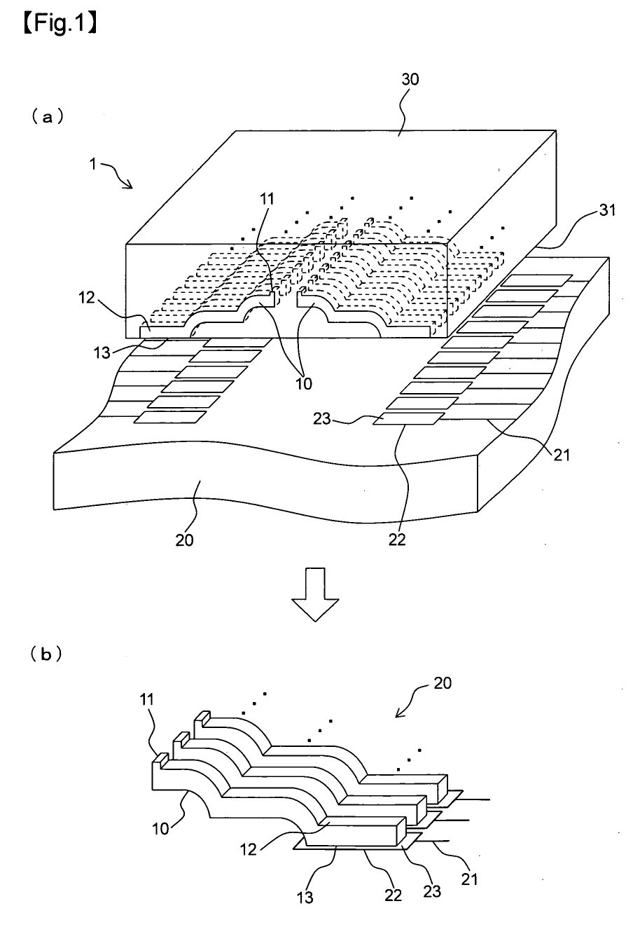

FIG. 2 is provided to explain the method for manufacturing the probe card of FIG. 1, showing a schematic cross-sectional diagram of a probe card manufacturing device.

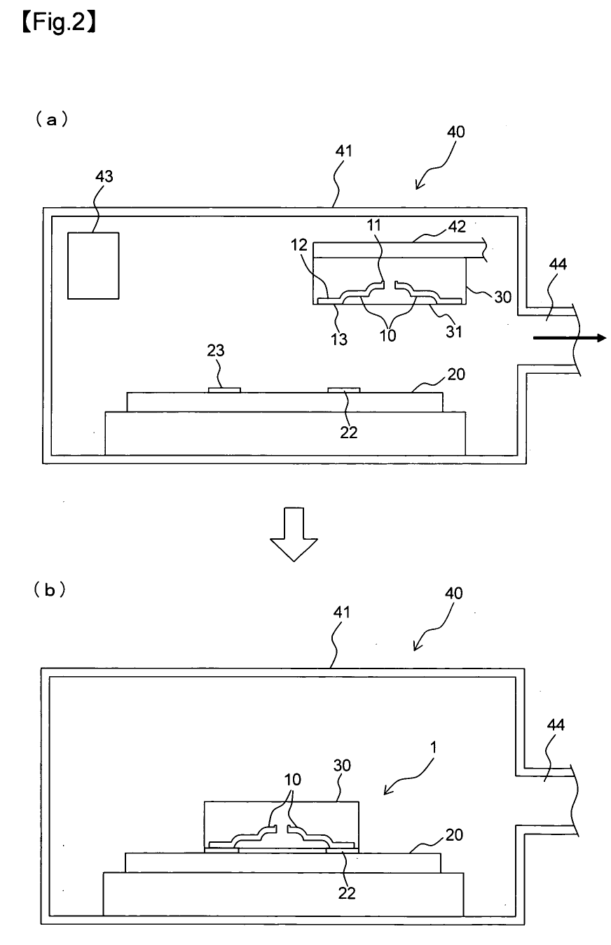

FIG. 3 is a flowchart showing an example of a joining process at normal temperature as the method for manufacturing the probe card of FIG. 1.

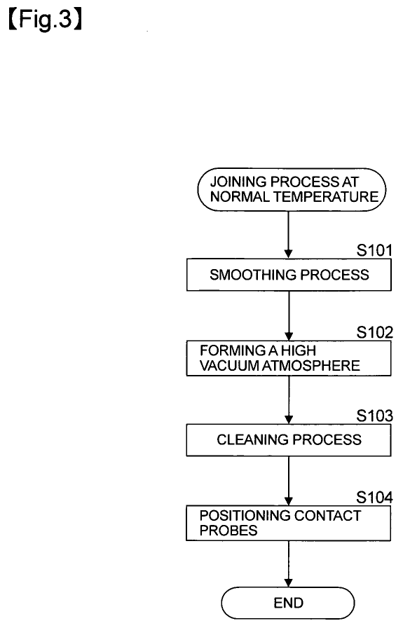

FIG. 4 is a model diagram to explain the principle of the joining process at normal temperature.

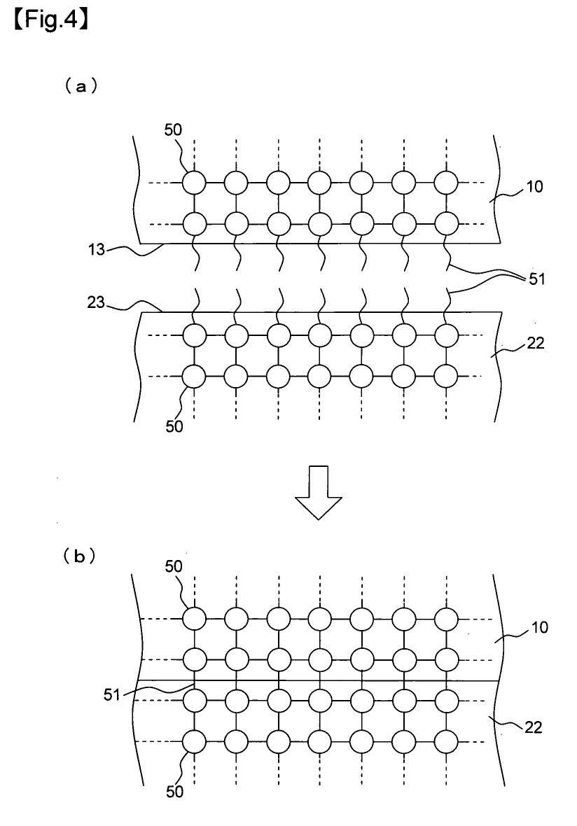

1. A probe card comprising:
contact probes for use in contact with a test object; and
a substrate containing electrode pads formed on the surface thereof to be connected to said contact probes, wherein:
each of junction interfaces of said contact probes and said electrode pads is made from the same metal material; and
said contact probes and said electrode pads are joined by associating the junction interfaces thereof with one another in vacuum.

2. A method for manufacturing a probe card wherein contact probes for use in contact with a test subject and electrode pads formed on the surface of a substrate are joined, the method comprising:
an interface forming step to form each of junction interfaces of said contact probes and said electrode pads with the same metal material;
an interface activating step to remove impurities attached to each of the junction interfaces of said contact probes and said metal pads in vacuum so as to activate each of the junction interfaces; and
an interface joining step to associate and join each of the junction interfaces of said contact probes and said metal pads while keeping a vacuum state after implementing said interface activating step.

3. The method according to claim 2, wherein said interface activating step includes irradiating each of the junction interfaces of said contact probes and said metal pads with ions so as to remove impurities attached to each of the junction interfaces in vacuum, thereby activating each of the junction interfaces.

4. The method according to claim 2 or 3, further comprising an interface smoothing step to smooth each of the junction interfaces of said contact probes and said electrode pads, wherein
said interface activating step is carried out after said interface smoothing step.
